(19) United States
(12) Patent Application Publication
(10) Pub. No.: US 2011/0143021 A1
(43) Pub. Date: Jun. 16, 2011

(54) CONFORMAL COATING SYSTEM AND METHOD

(75) Inventors: Corey A. Peterson, Grafton, WI (US); Martha A. Maxwell, Milwaukee, WI (US); Bruce W. Weiss, Whitefish Bay, WI (US)

(73) Assignee: Rockwell Automation Technologies, Inc., Mayfield Heights, OH (US)

(21) Appl. No.: 12/638,892

(22) Filed: Dec. 15, 2009

(51) Int. Cl. H05K 3/00; B05D 3/02; B05C 11/00; B05C 5/00

(52) U.S. Cl. 427/99.2; 118/663; 118/300

(57) ABSTRACT

A conformal coating system and method for coating a printed circuit board (PCB) is provided. The system comprises a coating station configured to coat the PCB with a coating material and without cleaning the PCB with a saponifier. A surface energy of the PCB is maintained above a target surface energy at least through the cleaning station to promote adhesion of the coating material.

### BACKGROUND

The invention relates generally to printed circuit board assemblies and more specifically to conformal coating method and system.

Printed circuit boards (PCBs) generally suffer degraded accuracy when its insulating surfaces are contaminated with ionic substances such as fingerprint residues, dust, and the like. In addition, in the presence of moisture, such ionic substances may become conductive, resulting in failure of some or all of components on the PCB.

Conformal coating material is typically applied on the surfaces of the printed circuit boards to act as protective layer against moisture, dust, chemicals, etc. The coating material also assists in reducing the effects of mechanical stress and vibrations on the PCB and its ability to cope in extreme temperatures.

In a typical conformal coating process, the PCB is first cleaned to remove all surface contamination to enable a coating to adhere to the surface of the PCB. The coating material is then applied on the PCB using one or more of a number of techniques such as spraying, dipping, brushing, etc. Subsequently, the coating is cured using suitable techniques such as air drying, ultraviolet drying and the like.

An additional step in most conformal coating processes include cleaning the coated PCB with a cleaning material to remove residual matter present on the surfaces of the board. Typically, the cleaning material comprises a saponifier and is used to remove process dirt. However, this process of washing the PCB with a saponifier increases the total cycle time of the conformal coating process which results in an increase in the total cost.

Therefore, there is a need for a cost effective method and system for application of a conformal coating on printed circuit boards while minimizing cycle time.

### BRIEF DESCRIPTION

Briefly, according to one embodiment of the invention, a method for coating a PCB is provided. The method comprises controlling and monitoring a parameter of surface energy of the PCB, coating the PCB with a coating material without cleaning the PCB with a saponifier, and curing the coating.

In another embodiment, a conformal coating system for coating a PCB is provided. The system a coating station configured to coat the PCB with a coating material without washing the PCB with a saponifier; wherein a surface energy of the PCB is maintained above a target surface energy to promote adhesion of the coating material.

In one embodiment, a method for coating a PCB is provided. The method comprising controlling and monitoring a surface energy of the PCB at about 50 dynes per square centimeter, coating the PCB with an ultraviolet cross-linkable polymer without cleaning the PCB with a saponifier, and curing the coating.

### DRAWINGS

These and other features, aspects, and advantages of the present invention will become better understood when the following detailed description is read with reference to the accompanying drawings in which like characters represent like parts throughout the drawings, wherein:

FIG. 1 is a block diagram of one embodiment of conformal coating system implemented according to one aspect of the invention;

FIG. 2 is a cross sectional view of printed circuit board implemented according to one aspect of the invention;

FIG. 3 and FIG. 4 are cross sectional views of a single bead of coating deposited on a printed circuit board; and

FIG. 5 is flow chart illustrating one method by which a printed circuit board is coated.

### DETAILED DESCRIPTION

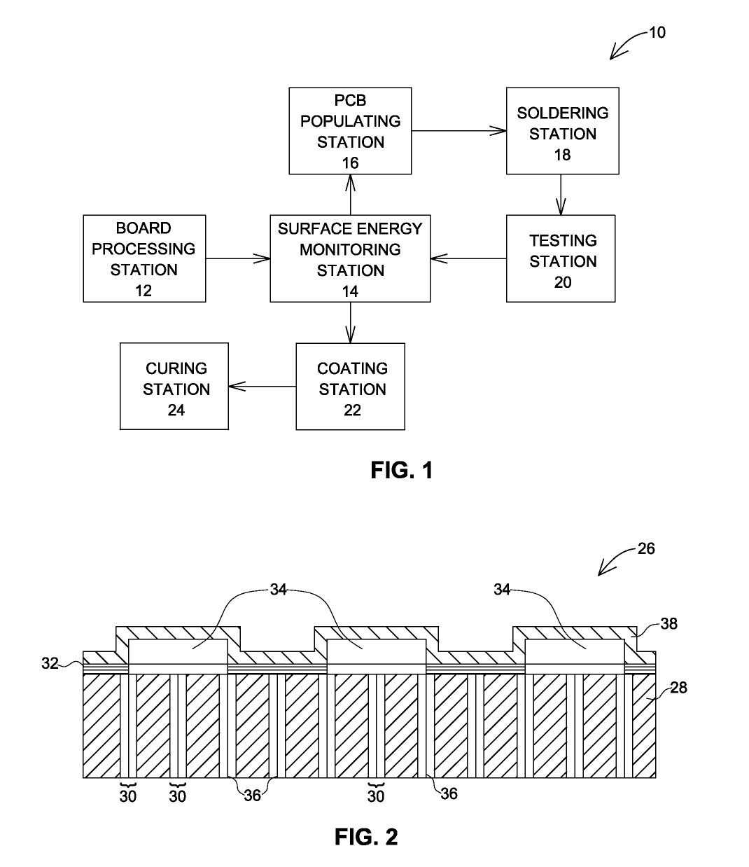

Turning now to the drawings, and referring first to FIG. 1, a conformal coating system is illustrated. FIG. 1 is a block diagram of one embodiment of a printed circuit board assembly system 10 implemented according to one aspect of the present invention. Board processing station 12 is configured to perform initial processing on the printed circuit boards. Initial processing may include steps such as etching patterns on the PCB and drilling holes on the PCB for receiving various electronic components.

Surface energy monitoring station 14 is configured to monitor a surface energy of the PCB. In one embodiment, the surface energy is monitored using Dyne pens. In one embodiment, the minimum surface energy is about 50 dynes/square centimeter. In a more specific embodiment, the minimum surface energy is about 44 dynes/square centimeter.

PCB populating station 16 is configured to populate the processed PCB with desired electronic components. The electronic components are placed or mounted on the printed circuit board to form a printed circuit board assembly. The electronic components comprise several component leads which are inserted into corresponding holes in the PCB. The populated boards are then soldered at soldering station 18.

Soldering station 18 is configured to electrically and mechanically couple the electronic components to the PCB. Soldering station may include a fluxer (not shown) where a spray of flux is applied to the bottom of the PCB. The board is then heated to a desired temperature. The PCB then receives molten solder which upon solidification electrically couples the component leads to the PCB.

Testing station 20 is configured to perform several tests on the populated PCB. The PCB is tested for functionality and also physical parameters such as voltage and frequency. The surface energy of the populated, soldered and tested PCB is again monitored by the surface energy monitoring station 14.

Coating station 22 is configured to coat the PCB with a coating material. In one embodiment, the coating material is a solid material. In a more specific embodiment, the coating material is an ultraviolet cross linkable polymer. In one embodiment, the coating material is sprayed on the PCB. In order for the coating to adhere effectively to the surface of the PCB, a desired amount of surface energy must be present on the board to assist adhesion.

Several parameters are required to be set on the coating applicator in order to obtain a desired thickness of the coating. In one embodiment, the thickness of the coating is controlled by controlling a speed of the spray nozzle. In another embodiment, the thickness is controlled by controlling a valve opening of the sprayer. The thickness of the coating is also dependent on a distance between the sprayer and the PCB surface. Another parameter that is controlled during the coating process is the valve turn-on time and turn-off time of the sprayer.

The above mentioned parameters such as valve opening, turn-on and turn-off times, distances between the sprayer and the PCB and the spray nozzle speeds are first set in the sprayer before the coating process is initiated. In one embodiment, the coating thickness is measured using a thickness gauge. In one embodiment, the thickness gauge uses eddy currents to measure the thickness of the coating.

Curing station 24 is configured to cure the coating on the PCB. In one embodiment, an ultraviolet (UV) oven is used to cure the coating. In one embodiment, the ultraviolet oven has at least two UV lamps. In one embodiment, a specific distance between the UV lamps and a surface of the PCB is maintained. In a further embodiment, the UV oven comprises at least two reflectors to reduce energy loss.

FIG. 2 is a cross sectional view of a coated PCB assembly implemented according to one aspect of the invention. PCB assembly 26 comprises a printed circuit board 28 with a plurality of holes 30 drilled through it. In one embodiment, the PCB comprises several hundred holes.

A layer of solder mask 32 is coated on a top surface of the PCB. The solder mask is a protective coating for copper traces of the PCB and prevents short circuits. In the illustrated embodiment, the solder mask 32 is coated on the top side of the PCB. However, the solder mask may be coated on a both sides of the PCB as well.

Electronic components 34 are mounted on the PCB 26. Component leads 36 are inserted in the corresponding holes of the PCB. The components are electrically and mechanically attached to the PCB by soldering the components leads. Conformal coating 38 is coated on the top of the PCB in the form of a thin layer. In one embodiment, the coating is a one hundred percent solid material.

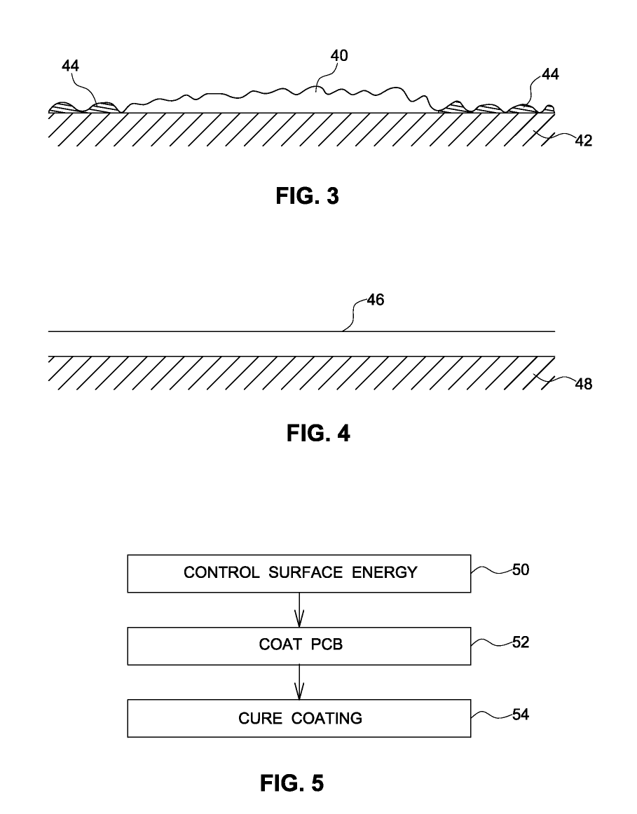

As described earlier, the conformal coating adheres to the surface of the PCB depending on the surface energy of the board. The total surface energy is determined based upon a specified surface energy for the PCB combined with a target surface energy due to processing, and further combined with a surface energy margin. The coating does not adhere adequately on a PCB with less surface energy as described below with reference to FIG. 3.

FIG. 3 is a diagrammatic view of a bead of coating coated on a board. Coating 40 is coated on board 42 with a low surface energy. In the illustrated embodiment, the surface energy is less than 44 Dynes per square centimeter. As can be seen, coating is not uniform and rough edges 44 are seen on either side of the bead. However, an increase in the surface energy greatly improves the adherence of the coating material is described with reference to FIG. 4 below.

FIG. 4 is a diagrammatic view of a bead of coating on a board with a specified. As can be seen, coating 46 on board 48 is uniform and without any rough edges. In one embodiment, the surface energy is about 50 dynes per square centimeter. In a more specific embodiment, the surface energy is about 44 dynes per square centimeter. The manner in which the PCB is coated is described in further detail below.

FIG. 5 is a flow chart illustrating one technique by which a printed circuit board is coated. At step 50, a surface energy of the PCB is monitored and controlled. The surface energy is an important parameter as it determines an adherence of the coating material. A low surface energy will not permit the coating material to adhere to the PCB.

Therefore, the surface energy is maintained at a specified value. The specified value of the surface energy is determined based upon a specified surface energy for the PCB, combined with a target surface energy due to processing, and further combined with a surface energy margin. In one embodiment, the surface energy is maintained at 44 Dynes per square centimeter. In one embodiment, the surface energy is monitored using Dyne pens.

At step 52, the PCB is coated with a coating material. In one embodiment, the coating material is sprayed on to the PCB using a sprayer. In one embodiment, the coating material is a solid material. In one embodiment, one side of the PCB is first coated and is followed by coating of the second side. In another embodiment, both sides of the PCB are simultaneously coated with the coating material.

At step 54, the coating is cured. In one embodiment, an ultraviolet oven is used to cure the coating. In one embodiment, the ultraviolet oven has two light sources. In a more specific embodiment, the ultraviolet oven comprises two light sources and two reflectors. The reflectors are configured to improve the light output from the light sources. The time taken to cure the coating is dependent on a speed at which the PCB is moved inside the oven. In one embodiment, a conveyor is used to move the PCB inside the oven. In one embodiment, the conveyor speed is set at 1.5 meters per minute.

The above described techniques provide several advantages such as providing an improved conformal coating for the printed circuit boards while reducing the cycle time. Due to the uniform coating that is obtained, the number of failures caused by conductive dust, etc. is substantially reduced. In addition, since the board does not need cleaning with a saponifier, the cycle time is reduced. Also, since the coating material is non-solvent based, the generation of volatile organic compounds is eliminated.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method for coating a printed circuit board (PCB), the method comprising:
controlling and monitoring a parameter of surface energy of the PCB;
coating the PCB with a coating material without cleaning the PCB with a saponifier; and
curing the coating.

2. The method of claim 1, wherein coating comprising spraying the coating material on the PCB using a sprayer.

3. The method of claim 2, further comprising controlling a spraying speed of the spray nozzle.

4. The method of claim 1, further comprising controlling a thickness of the coating material.

5. The method of claim 1, wherein the surface energy is controlled to remain above about 50 dynes per square centimeter.

6. The method of claim 5, wherein the surface energy is controlled to remain above about 44 dynes per square centimeter.

7. The method of claim 1, wherein the controlled surface energy is determined based upon a specified surface energy for the PCB, combined with a target surface energy due to processing, and further combined with a surface energy margin.

8. The method of claim 1, wherein the coating material is a 100 percent solid.

9. The method of claim 1, wherein the coating material is an ultraviolet cross-linkable polymer.

10. A conformal coating system for coating a printed circuit board (PCB), the system comprising:
a coating station configured to coat the PCB with a coating material; wherein a surface energy of the PCB is maintained above a target surface energy to promote adhesion of the coating material.

11. The system of claim 10, wherein the coating station comprises a coating applicator.

12. The system of claim 11, wherein the coating applicator comprises a sprayer.

13. The system of claim 12, wherein the coating station is configured to control a spraying speed of the sprayer.

14. The system of claim 12, wherein the coating station is configured to control a opening of a valve of the sprayer.

15. The system of claim 11, wherein the surface energy is controlled to remain at about 50 dynes per square centimeter.

16. The system of claim 15, wherein the surface energy is controlled to remain above about 44 dynes per square centimeter.

17. The system of claim 11, wherein the coating material is a 100 percent solid.

18. A method for coating a printed circuit board (PCB), the method comprising:
controlling and monitoring a surface energy of the PCB at about 50 dynes per square centimeter;
coating the PCB with an ultraviolet cross-linkable polymer without cleaning the PCB with a saponifier; and
curing the coating.

19. The method of claim 18, wherein the surface energy is controlled to remain above about 44 dynes per square centimeter.

20. The method of claim 18, wherein the curing comprises using an ultraviolet light.
